(19) United States
(12) Patent Application Publication
(10) Pub. No.: US 2026/0130243 A1
(43) Pub. Date: May 7, 2026

(54) SEMICONDUCTOR DEVICE AND MANUFACTURING METHOD THEREOF

(71) Applicants: Taiwan Semiconductor Manufacturing Company, Ltd., Hsinchu (TW); TSMC Arizona Corporation, Phoenix, AZ (US)

(72) Inventors: Xuewen Tang, Hsinchu (TW); Ji-Feng Ying, Hsinchu City (TW); Wen-Hsien CHUANG, Taipei City (TW); Yao-Chun Chuang, Hsinchu City (TW)

(73) Assignees: Taiwan Semiconductor Manufacturing Company, Ltd., Hsinchu (TW); TSMC Arizona Corporation, Phoenix, AZ (US)

(21) Appl. No.: 18/938,249

(22) Filed: Nov. 5, 2024

(51) Int. Cl. H01L 23/538; H01L 23/00; H01L 23/31; H01L 23/48; H01L 25/00; H01L 25/065; H01L 25/10

(52) U.S. Cl. CPC H10W 70/614; H10W 70/611; H10W 70/65; H10W 90/00; H10W 20/20; H10W 70/60; H10W 74/111; H10W 90/724

(57) ABSTRACT

A semiconductor device includes a substrate, a first die embedded in the substrate, a plurality of first connectors located between and electrically connected to the first die and the substrate. a second die bonded to a first surface of the substrate, a third die bonded to the first surface of the substrate, an encapsulant encapsulating the second die and the third die, and a plurality of second connectors located on a second surface opposite to the first surface of the substrate.

### BACKGROUND

Semiconductor packages are used in a variety of electronic applications, such as personal computers, cell phones, digital cameras, and other electronic equipment. In terms of the packaging used for integrated circuit components or semiconductor dies, one or more dies or packages are generally bonded to a circuit carrier (e.g., a system board, a printed circuit board, or the like) for electrical connections to other external devices or electronic components. To respond to the increasing demand for miniaturization, higher speed and better electrical performance, more creative packaging and assembling techniques are actively researched.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1D are cross-sectional view illustrating a method of forming a first die of the semiconductor device according to a first embodiment of the disclosure.

FIG. 2A to FIG. 2F are cross-sectional view illustrating a method of forming a semiconductor device according to an embodiment of the disclosure.

FIG. 3 is cross-sectional view illustrating a semiconductor device according to another embodiment of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

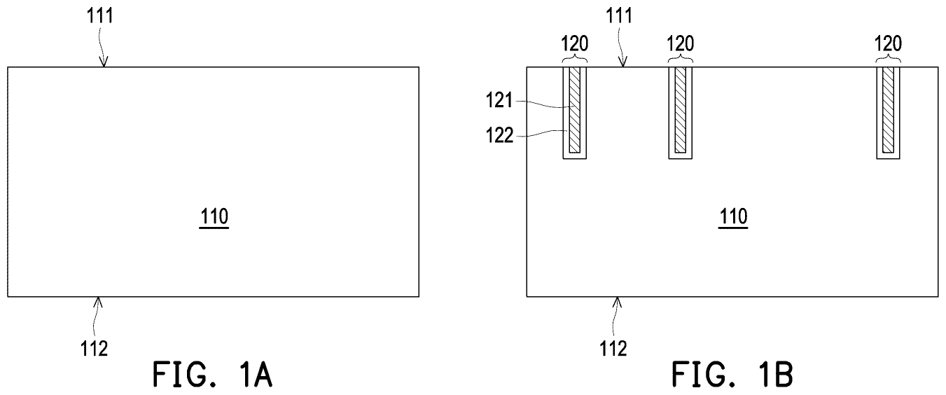

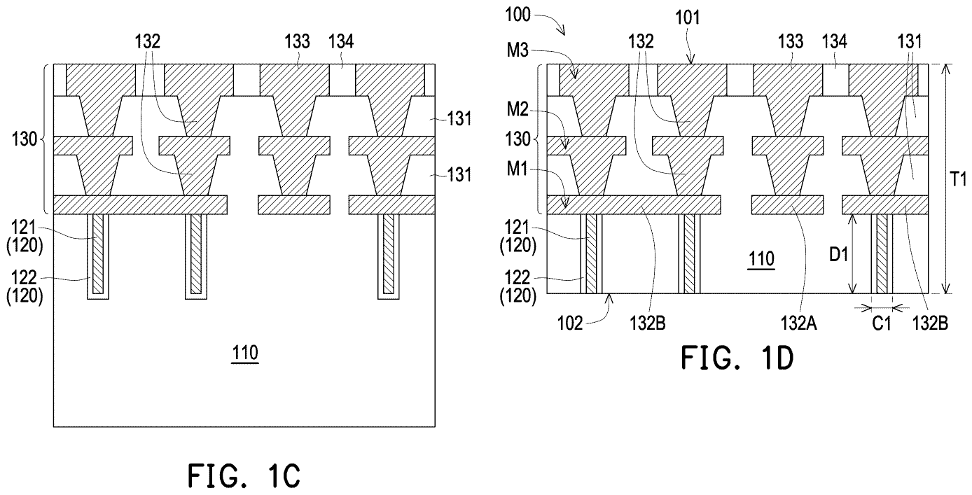

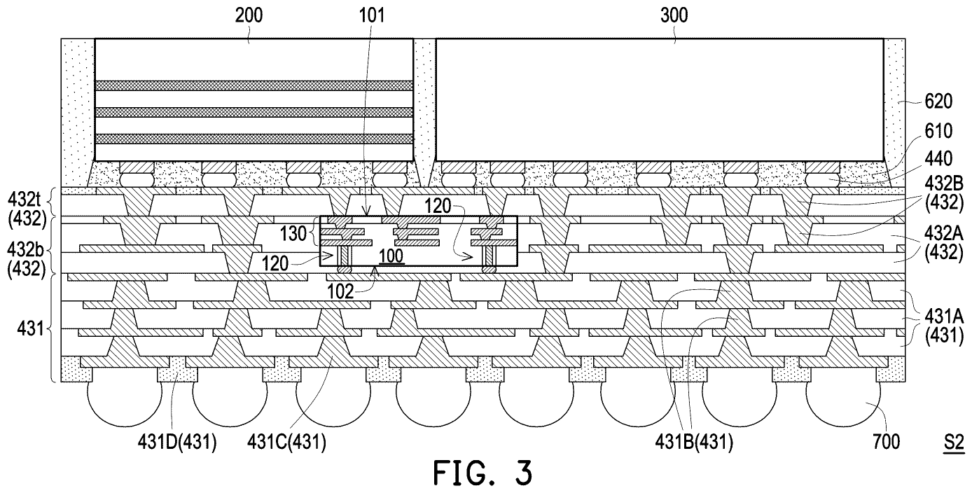

FIG. 1A to FIG. 1D are cross-sectional view illustrating a method of forming a first die of the semiconductor device according to a first embodiment of the disclosure. FIG. 1A to FIG. 1D are a schematic cross-sectional view illustrating the preparation of a first die for subsequent processes according to the embodiment of the disclosure. FIG. 3 is cross-sectional view illustrating a semiconductor device according to another embodiment of the disclosure.

Referring to FIG. 1A, a base material layer 110 is provided, for example, the base material layer 110 is a semiconductor substrate, such as a bulk semiconductor, a semiconductor-on-insulator (SOI) substrate, a semiconductor on sapphire substrate, other supporting substrate (e.g., quartz, glass, etc.), combinations thereof, or the like, which may be doped or undoped. In some embodiments, the base material layer 110 is made of silicon or other semiconductor materials. Alternatively, the base material layer 110 includes other elementary semiconductor materials such as germanium, gallium arsenic, or other suitable semiconductor materials. In some embodiments, the base material layer 110 may further include other features such as various doped regions, buried layers, and/or epitaxy layers. Moreover, in some embodiments, the base material layer 110 is made of an alloy semiconductor such as silicon germanium, silicon germanium carbide, gallium arsenic phosphide, or gallium indium phosphide. Herein, the base material layer 110 may have a first surface 111 and a second surface 112, and the second surface 112 is opposite to the first surface 111.

Referring to FIG. 1B, a plurality of through vias 120 are formed in the base material layer 110. In some embodiments, each of the through vias 120 includes a conductive post 121 and a liner 122 surrounding the sidewalls and bottom surface of the conductive post 121 to separate the conductive post 121 from the base material layer 110. The conductive post 121 may include copper, copper alloys, aluminum, aluminum alloys, Ta, TaN, Ti, TiN, CoW or combinations thereof. The liner 122 may include dielectric material, such as silicon oxide, silicon nitride, or the like. In some embodiments, when the through vias 120 are initially formed, the through vias 120 are embedded in the base material layer 110 and may not extend to the second surface 112 (such as the back surface) of the base material layer 110.

In some embodiments, the through vias 120 are formed by following steps. First, the base material layer 110 is patterned to form openings. In various embodiments, the patterning may be formed by an acceptable process, such as a lithographic process including forming a photo-sensitive material on the base material layer 110, and then exposing the photo-sensitive material to light, and after exposure, the photo-sensitive material is developed and etched. Then, the liner 122 and the conductive post 121 may be formed in the openings and extended to a top surface 111 of the base material layer 110. At last, a planarization process is performed, such that a top surface of the liner 122, a top surface of the conductive post 121 and a top surface 111 of the base material layer 110 are coplanar. The planarization process may be, for example, a grinding or a chemical-mechanical polish (CMP).

Referring to FIG. 1C, an interconnect structure 130 is formed over the through vias 120, for example, and the interconnect structure 130 includes a dielectric structure 131 and a conductive structure 132 embedded in the dielectric structure 131. In some embodiments, the dielectric structure 131 includes multiple layers of dielectric layers, and the conductive structure 132 includes multiple layers of conductive features formed in the dielectric layers. The conductive features of the conductive structure 132 are connected to the through vias 120 formed in the base material layer 110 to form a functional circuit. In some embodiments, the through vias 120 may extend into the interconnect structure 130 to be in physical and electrical contact with the conductive features of the interconnect structure 130.

In some embodiments, the dielectric layers of the dielectric structure 131 include an inter-layer dielectric (ILD) layer formed over the base material layer 110. In some embodiments, the dielectric layers are formed of a low-K dielectric material or an extreme low-K (ELK) material, such as an oxide, silicon dioxide, borophosphosilicate glass (BPSG), phosphosilicate glass (PSG), fluorinated silicate glass (FSG), SiOxCy, Spin-On-Glass, Spin-On-Polymers, silicon carbon material, compounds thereof, composites thereof, combinations thereof, or the like. The dielectric layers may include any suitable number of dielectric material layers. The conductive features of the conductive structure 132 may be embedded in the dielectric layers, and includes multiple layers of metal lines and vias (not shown). The conductive features may include metal, metal alloy, the like or combinations thereof, such as tungsten (W), copper (Cu), copper alloys, aluminum (Al), aluminum alloys, or combinations thereof.

In some embodiments, the interconnect structure 130 further includes a plurality of pads 133 and a passivation layer 134 over the dielectric structure 131 and the conductive structure 132. The pads 133 are electrically connected to the topmost conductive feature of the conductive structure 132, and the passivation layer 134 may expose a portion of the pads 133 for further electrical connection. The pads 133 are metallic pads, such as aluminum pads. The passivation layer 134 includes a nitride such as silicon nitride. In some embodiments, the interconnect structure 130 may be formed by dual damascene process. In some embodiment, the passivation layer 134 may partially cover the pads 133 and expose a portion of the pads 133.

Referring to FIG. 1D, the base material layer 110 is thinned by, for example, grinding process, chemical mechanical polishing (CMP) process, etching processes, combinations thereof, or other suitable thinning techniques to form the first die 100. In some embodiments, the first die 100 may be an active or a passive device. A wide variety of devices such as transistors, capacitors, resistors, inductors, combinations of these, and the like may be used. For example, a thinning process is performed on the second surface 112 (backside) of the base material layer 110 so that the through vias 120 are accessibly revealed through the second surface 112 of the base material layer 110. In some embodiments, the through vias 120 may be referred to as through substrate vias (TSVs) or through silicon vias when the base material layer 110 is a silicon substrate. In some embodiments, top surfaces of the pads 133 and a top surface of the passivation layer 134 constitute a first surface 101 of the first die 100, and the revealed surfaces of the through vias 120 and the thinned second surface 112 of the base material layer 110 constitute a second surface 102 the first die 100, wherein the second surface 102 is opposite to the first surface 101.

In FIG. 1D, a bottommost layer of the conductive structure 132 of interconnect structure 130 includes a first portion 132A and a pair of second portions 132B, the first portion 132A is isolated from the through vias 120, and the pair of second portions 132B are electrically connected to the through vias 120. In some embodiments, the base material layer 110 can refer to a base portion, the first portion 132A can refer to a power portion (or ground portion), the second portions 132B can refer to signal portions, the second portions 132B may be penetrated through the base material layer 110, and the first portion 132A is floated in the base material layer 110, thereby the first portion 132A may provide power routing, and the second portions 132B and the through vias 120 may provide I/O routing, and electrical routing within the semiconductor device is changed, the bottommost layer of the conductive structure 132 is designed with two different electrical paths.

For example, the interconnect structure 130 may have signal portions includes a first interconnect layer (such as the second portions 132B) and the through vias 120, the power portion includes a second interconnect layer (such as the first portion 132A), and the second interconnect layer is spaced from the through vias 120.

In some embodiments, after thinning, a thickness T1 of the first die 100 is greater than or equal to about 30 μm, for example, the thickness T1 of the first die 100 is greater than or equal to about 40 μm. Further, a critical dimension C1 of each of the through vias 120 is greater than or equal to about 0.5 μm. Also, a depth D1 of the each of the through vias 120 is greater than or equal to about 5 μm.

In the present embodiment, three metal layers which a first layer M1, a second layer M2, a third layer M3 are formed within the interconnect structure 130 of first die 100 and stacked on the through vias 120. In the unillustrated embodiment, four metal layers M1, M2, M3, and M4 (not shown) are formed within the interconnect structure 130 of first die 100 and stacked on the through vias 120, the metal layer M1 and the metal layer M3 may serve as ground planes. The metal layer M2 and the metal layer M4 may serve as signal layers.

In some embodiments, vias of conductive structure 132 of interconnect structure 130 are tapered, a size of each of vias is gradually smaller toward the through vias 120, for example, a size of bottom portion of each of vias close to the through vias 120 is smaller than a size of top portion of each of vias away to the through vias 120.

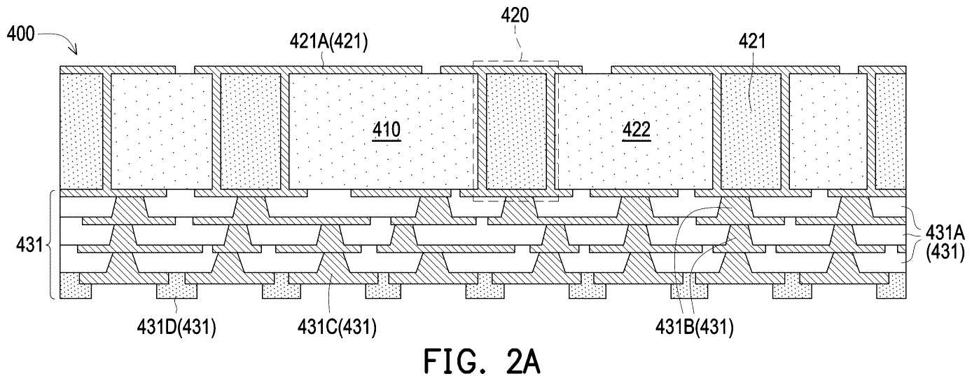

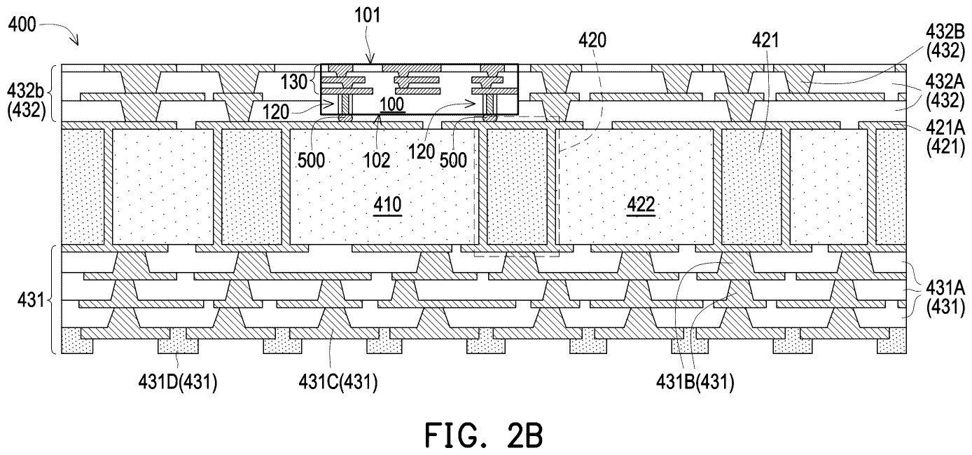

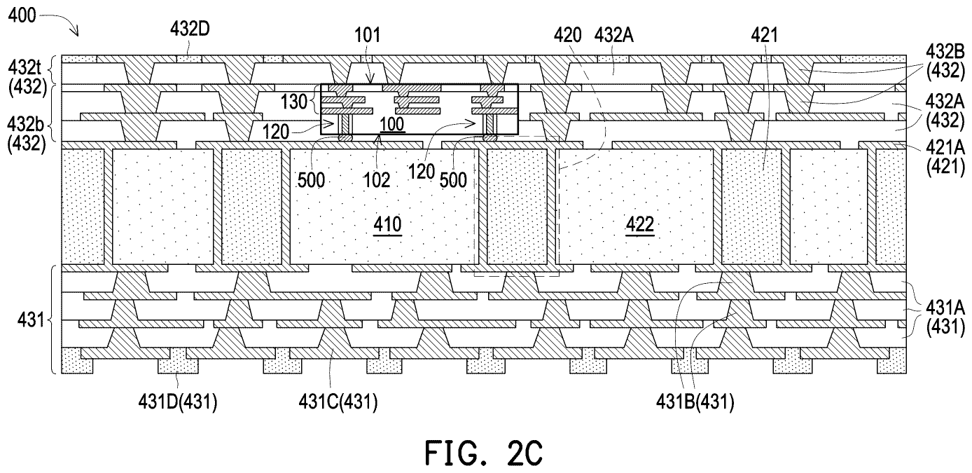

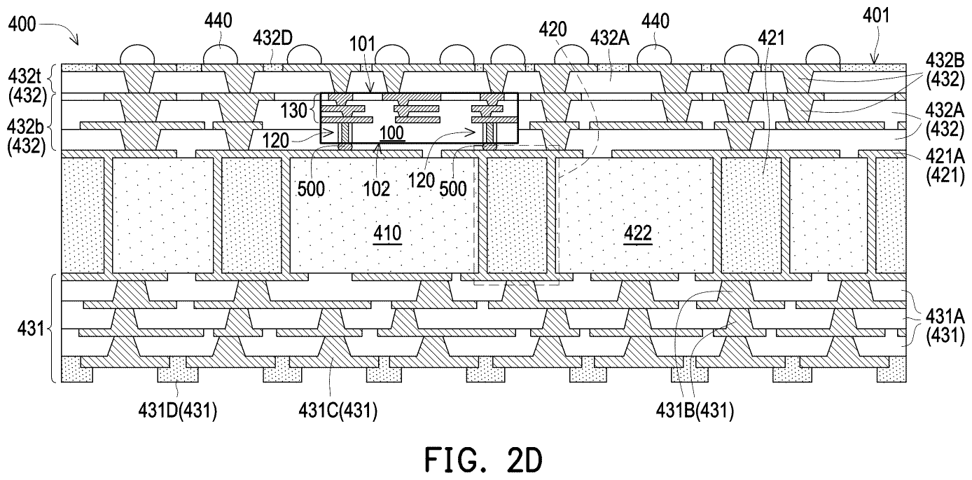

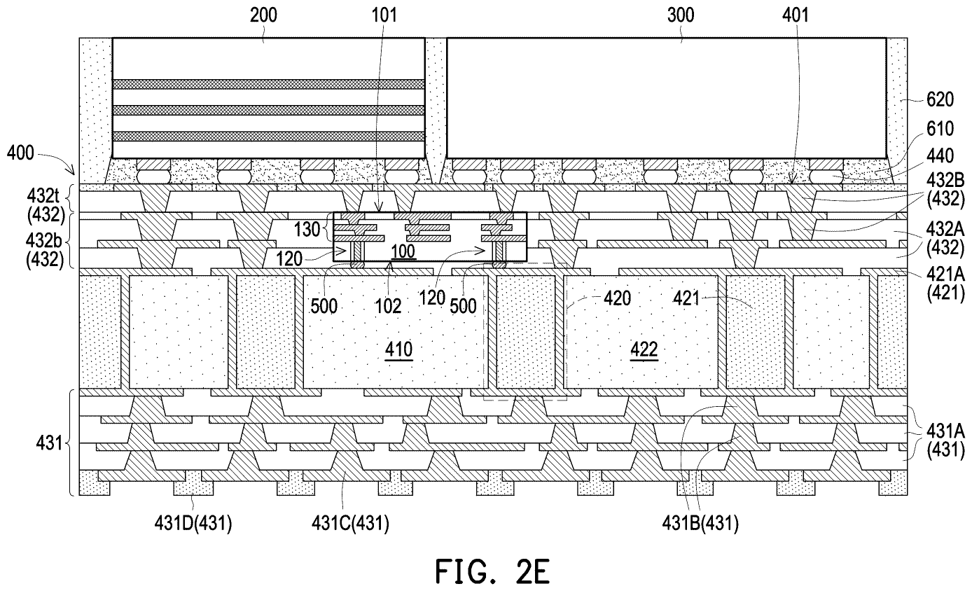

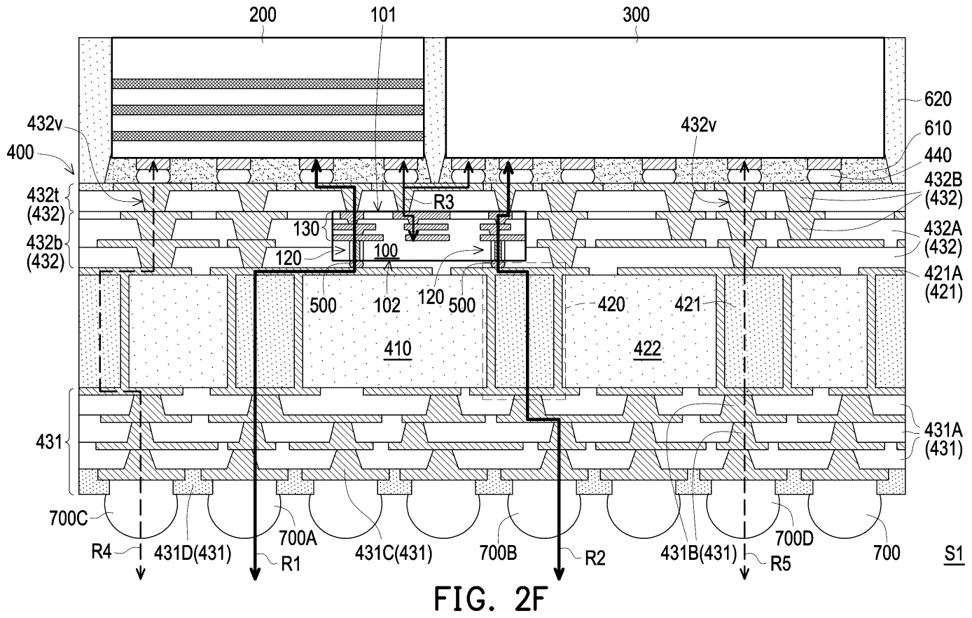

FIG. 2A to FIG. 2F are cross-sectional view illustrating a method of forming a semiconductor device according to an embodiment of the disclosure. Herein, the first die 100 in FIG. 2B to FIG. 2F is extract right portion.

Referring to FIG. 2A, a substrate 400 is provided. The substrate 400 in FIG. 2A is an intermediate stage and the substrate 400 is finished in FIG. 2D. Moreover, before being assembled to the first die 100, the substrate 400 may be processed according to applicable manufacturing processes to form redistribution structures in the substrate 400.

For example, the substrate 400 includes a core layer 410. In some embodiments, the core layer 410 may be formed of one or more layers of glass fiber, resin, filler, pre-preg, epoxy, silica filler, Ajinomoto Build-up Film (ABF), polyimide, molding compound, other materials, and/or combinations thereof. A plurality of conductive vias 420 may be formed extending through the core layer 410. Each of the conductive vias 420 may include a conductive layer 421 such as copper, a copper alloy, or other conductors, and may include a barrier layer (not shown), liner (not shown), seed layer (not shown), and/or a filler 422 such as suitable insulators, in some embodiments. The conductive vias 420 provide vertical electrical connections from one side of the core layer 410 to the other side of the core layer 410. In some embodiments, the conductive layer 421 has conductive features 421A at one side of the core layer 410.

In some embodiments, holes for the conductive vias 420 may be formed using a drilling process, photolithography, a laser process, or other methods, as examples, and the holes of the conductive vias 421 are then filled or plated with conductive material. In some embodiments, the conductive vias 420 are hollow conductive through vias having centers that are filled with an insulating material.

In FIG. 2A, a redistribution structure 431 are formed on one side opposite to the conductive features 421A of the conductive vias 420. The redistribution structure 431 is electrically coupled to the conductive vias 420. The redistribution structure 431 may include dielectric layers 431A, formed of ABF, pre-preg, or the like, and conductive feature 431B. The conductive feature 431B has line portions on and extending along a major surface of a respective dielectric layer, and has via portions extending through the respective dielectric layer. Moreover, the redistribution structure 431 may include under-bump metallurgies (UBMs) 431C for external connection, and solder resists 431D protecting the features of the redistribution structures 431. Further, more or fewer dielectric layers and conductive feature may be formed in the redistribution structures 431 than shown in FIG. 2A.

Referring to FIG. 2B, the first die 100 is bonded and electrically connected to the substrate 400, for example, a plurality of first connectors 500 are formed on the conductive feature 421A of the conductive vias 421, such that the first connectors 500 may be in contact with the second surface 102 of the first die 100 and a top surface of the conductive feature 421A of the conductive vias 421. In some embodiments, the first connectors 500 are formed by initially forming a layer of solder through evaporation, electroplating, printing, solder transfer, ball placement, or the like. Once a layer of solder has been formed on the structure, a reflow may be performed in order to shape the material into the desired bump shapes. In some embodiments, the first connectors 500 are aligned with the through vias 120, and the first connectors 500 are located between the through vias 120 and the conductive feature 421A of the conductive vias 421. Further, the through vias 120 may extend from the interconnect structure 130 to connect to the plurality of first connectors 500.

On the other hand, a first redistribution process (such as a build-up process) may be performed on the core layer 410 to form a bottom portion 432b of a redistribution structure 432 located beside the first die 100, wherein the conductive feature 421A of the conductive vias 421 may be serve as portions of the bottom portion 432b of a redistribution structure 432. In some embodiments, the bottom portion 432b of the redistribution structure 432 includes dielectric layers 432A, formed of ABF, pre-preg, or the like, and conductive feature 432B. The conductive feature 432B has line portions on and extending along a major surface of a respective dielectric layer 432A, and has via portions extending through the respective dielectric layer 432A. In some embodiments, the bottom portion 432b of the redistribution structure 432 may surround the first die 100.

In some embodiments, a top surface of the interconnect structure 130 of the first die 100 and a top surface of the bottom portion 432b of the redistribution structure 432 are coplanar. In some implementations, after bonding the first die 100, the first redistribution process is performed by suitable process design. In some implementations, before bonding the first die 100, the first redistribution process is performed by suitable process design.

Referring to FIG. 2C, a second redistribution process (such as a build-up process) may be performed on the first die 100 and the bottom portion 432b of the redistribution structure 432 to form a top portion 432t of the redistribution structure 432. In some embodiments, the top portion 432t of the redistribution structure 432 includes another dielectric layers 432A, formed of ABF, pre-preg, or the like, and another conductive feature 432B. In this way, the first die 100 is inserted laterally between the conductive features 432B of the substrate 400, and the first die 100 is embedded in the redistribution structure 432 and electrically connected to the substrate 400 by the first connectors 500. Moreover, the redistribution structure 432 may include solder resists 432D protecting the features of the redistribution structures 432.

In some embodiments, the first die 100 is located between the conductive feature 432B of the top portion 432t of the redistribution structure 432 and the conductive feature 432B of the bottom portion 432b of the redistribution structure 432, the first surface 101 of the first die 100 is in contact with the conductive feature 432B of the top portion 432t of the redistribution structure 432 and the second surface 102 of the first die 100 is in contact with the first connectors 500.

Referring to FIG. 2D, a plurality of conductive connectors 440 are formed on a first surface 401 of the substrate 400. The conductive connectors 440 allow for physical and electrical connection between dies (such as a second die 200 and a third die 300 as shown in FIG. 2E) and the substrate 400. The conductive connectors 440 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 440 may include a conductive material such as solder, copper, aluminum, gold, nickel, silver, palladium, tin, the like, or a combination thereof. In some embodiments, the conductive connectors 440 are formed by initially forming a layer of solder through evaporation, electroplating, printing, solder transfer, ball placement, or the like. Once a layer of solder has been formed on the structure, a reflow may be performed in order to shape the material into the desired bump shapes.

In the unillustrated embodiment, the conductive connectors comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Referring to FIG. 2E, a plurality of dies such as two IC dies (the second die 200 and the third die 300) are bonded to the first surface 401 of the substrate 400. The second die 200 and the third die 300 may be partially overlapped the first die 100 in a vertical direction. The second die 200 and the third die 300 have bond pads respectively that are bonded to the conductive connectors 440 to connect the portions of the conductive features 432B below the second die 200 and third die 300. In some embodiments, the bond pads are made of a conductive material. In some embodiments, the second die 200 and the third die 300 are electrically connected to the interconnect structure 130.

In some embodiments, the second die 200 and the third die 300 may be placed on the conductive connectors 440 using a pick and place process or another suitable process and by flip chip bonding process or other suitable bonding process. In some embodiments, the conductive connectors 440 are reflowed to attach the second die 200 and the third die 300 to the redistribution structure 432 of the substrate 400. The second die 200 and the third die 300 may be coupled to conductive features 432B of the redistribution structure 432 of the substrate 400.

In some embodiments, orthographic projections of the second die 200 and the third die 300 on the substrate 400 covers the first die 100, for example, the first die 100 is partially overlapped the second die 200 in the vertical direction and the first die 100 is partially overlapped the third die 300 in the vertical direction. In an embodiment, the first die 100 is provided under and connects to the second die 200 and the third die 300.

In some embodiments, the second die 200 and the third die 300 may be stacked devices that include multiple semiconductor substrates. For example, the second die 200 and the third die 300 may be an input/output (I/O) die (SOC die) or a memory device such as a hybrid memory cube (HMC) module, a high bandwidth memory (HBM) module, or the like that includes multiple memory dies. In such embodiments, the second die 200 and the third die 300 includes multiple semiconductor substrates interconnected by through-substrate vias (TSVs). Each of the semiconductor substrates may (or may not) have an interconnect structure. In some embodiments, the second die 200 and the third die 300 may be HPC/AI Data Center chip in 3DIC package.

In FIG. 2E, an underfill 610 may be formed surrounding the conductive connectors 440 between the second die 200, the third die 300 and located on the redistribution structure 432 of the substrate 400. The underfill 610 may reduce stress and protect the joints resulting from the reflowing of the conductive connectors 440. The underfill 610 may be formed by a capillary flow process, or may be formed by a suitable deposition method.

Further, an encapsulant 620 is formed to encapsulate the second die 200 and the third die 300. The encapsulant 620 may be a molding compound, epoxy, or the like, and may be applied by compression molding, transfer molding, or the like. The encapsulant 620 may be formed over the substrate 400 laterally. The encapsulant 620 extends between the second die 200, the third die 300. In some embodiments, the encapsulant 620 surrounds the second die 200, the third die 300.

In some embodiments, the encapsulant 620 can undergo a grinding process to expose top surfaces of the second die 200, the third die 300 and top surfaces of the second die 200, the third die 300 and top surfaces of the encapsulant 130 are level after the grinding process. In some embodiments, the grinding may be omitted.

Referring to FIG. 2F, a plurality of second connectors 700 are formed on the redistribution structure 431 of the substrate 400 to form a semiconductor device S1, for example, the UBMs 431C may be located between the substrate 400 and second connectors 700 to provide electrical connection. In some embodiments, the second connectors 700 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 700 may include a conductive material such as solder, copper, aluminum, gold, nickel, silver, palladium, tin, the like, or a combination thereof.

In present embodiment, the second die 200 is electrically connected to the second connectors 700 through the first die 100 and the first connector 500 (left side in the drawing) to form a first signal routing R1, and the third die 300 is electrically connected to the second connectors 700 through the first die 100 and another first connector 500 (right side in the drawing) to form a second signal routing R2. Therefore, I/O signal latency may be reduced and the performance of the second die 200 and the third die 300 may be improved by the design of the first connectors 500 and the first die 100 (the embedded die with the through vias 120).

In some embodiment, the second connectors 700 includes a plurality of signal terminals electrically connected to the first die 100, for example, the second die 200 is electrically connected to the signal terminal 700A and the third die 300 is electrically connected to the signal terminal 700B directly for signal routing, such that electrical path through the first die 100 with a much shorter distance reducing its I/O signal latency.

In some embodiment, the through vias 120 of the first die 100 and the first connectors 500 may provide the backside interconnect to the second connectors 700 through the conductive vias 420, the redistribution structures 432 and 431.

In some embodiment, the second die 200 is electrically connected to the third die 300 through the first die 100 (central portion in the drawing) and the conductive feature 432B of the redistribution structure 432 to form a power routing R3. In some embodiment, the semiconductor device S1 may further include a plurality of vertical stacked vias 432v located beside the first die 100, and the second die 200 is electrically connected to a power terminal 700C of the second connectors 700 through the vertical stacked vias 432v of the redistribution structure 432 to form a power routing R4, and the third die 300 is electrically connected to a power terminal 700D of the second connectors 700 through another the vertical stacked vias 432v of the redistribution structure 432 to form a power routing R5.

In embodiment of FIG. 2A to FIG. 2F, the core layer 410 is existed, however, in the other one embodiment of FIG. 3, a semiconductor device S2 may be omitted the core layer 410 for design requirement, thereby the redistribution structure 432 may be in contact with the redistribution structure 431.

In accordance with some embodiments of the present disclosure, a semiconductor device includes a substrate, a first die embedded in the substrate, a plurality of first connectors located between and electrically connected to the first die and the substrate, a second die bonded to a first surface of the substrate, a third die bonded to the first surface of the substrate, an encapsulant encapsulating the second die and the third die, and a plurality of second connectors located on a second surface opposite to the first surface of the substrate. In an embodiment, the substrate includes a first conductive feature and a second conductive feature, the first die is located between the first conductive feature and the second conductive feature, the first conductive feature is connected to a first surface of the first die and the plurality of first connectors are connected to a second surface opposite to the first surface of the first die. In an embodiment, the first die includes an interconnect structure and a plurality of through vias, the plurality of through vias are located between the interconnect structure and the plurality of first connectors, and the plurality of through vias extend from the interconnect structure to the plurality of first connectors. In an embodiment, the interconnect structure includes a first portion and a pair of second portions, the first portion is isolated from the plurality of through vias, and the pair of second portions are electrically connected to the plurality of through vias. In an embodiment, the second die and the third die are electrically connected to each other through the first portion. In an embodiment, the plurality of second connectors comprises a plurality of signal terminals electrically connected to the first die through the plurality of first connectors. In an embodiment, the substrate includes a core layer, a first redistribution structure located on a first surface of the core layer, and a second redistribution structure located on a second surface opposite to the first surface of the core layer, wherein the first die is surrounded by the first redistribution structure. In an embodiment, the first die is provided under and connects to the second die and the third die.

In accordance with some embodiments of the present disclosure, a semiconductor device includes a substrate, a first die embedded in the substrate, a plurality of first connectors located between and electrically connected to the first die and the substrate, a second die located on a first surface of the substrate, a third die located on the first surface of the substrate, an encapsulant encapsulating the second die and the third die, and a plurality of second connectors located on a second surface opposite to the first surface of the substrate, wherein a first signal routing between the second die and the plurality of second connectors is provided through one of the plurality of first connectors and the first die and a second signal routing between the third die and the plurality of second connectors is provided through another one of the plurality of first connectors and the first die. In an embodiment, the first die includes a base portion, a power portion and a pair of signal portions, the pair of signal portions are penetrated through the base portion, and the power portion is floated in the base portion. In an embodiment, the first signal routing and the second signal routing pass through the pair of signal portions. In an embodiment, each of the pair of signal portions includes a first interconnect layer and a plurality of through vias, the power portion includes a second interconnect layer, and the second interconnect layer is spaced from the plurality of through vias. In an embodiment, orthographic projections of the second die and the third die on the substrate covers the first die. In an embodiment, the first die is partially overlapped the second die in a vertical direction and the first die is partially overlapped the third die in the vertical direction. In an embodiment, the first die is inserted between a plurality of conductive features of the substrate.

In accordance with some embodiments of the present disclosure, a manufacturing method of a semiconductor device includes providing a first die; embedding and electrically connected the first die in a substrate by a plurality of first connectors; bonding a second die to a first surface of the substrate; bonding a third die to the first surface of the substrate; forming a plurality of second connectors located on a second surface opposite to the first surface of the substrate, wherein a first signal routing between the second die and the plurality of second connectors and a second signal routing between the third die and the plurality of second connectors are configured by the first die respectively. In an embodiment, the manufacturing method of a semiconductor device further includes: forming an interconnect structure on a base material layer and a plurality of through vias in the base material layer to form the first die. In an embodiment, portions of the substrate are formed by a plurality of redistribution processes. In an embodiment, a plurality of conductive features formed by the plurality of redistribution processes is configured to surround. In an embodiment, the first die is a passive device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first die, embedded in the substrate;
a plurality of first connectors, located between and electrically connected to the first die and the substrate;
a second die, bonded to a first surface of the substrate;
a third die, bonded to the first surface of the substrate;
an encapsulant, encapsulating the second die and the third die; and
a plurality of second connectors, located on a second surface opposite to the first surface of the substrate.

2. The semiconductor device as claimed in claim 1, wherein the substrate comprises a first conductive feature and a second conductive feature, the first die is located between the first conductive feature and the second conductive feature, the first conductive feature is connected to a first surface of the first die and the plurality of first connectors are connected to a second surface opposite to the first surface of the first die.

3. The semiconductor device as claimed in claim 1, wherein the first die comprises an interconnect structure and a plurality of through vias, the plurality of through vias are located between the interconnect structure and the plurality of first connectors, and the plurality of through vias extend from the interconnect structure to the plurality of first connectors.

4. The semiconductor device as claimed in claim 3, wherein the interconnect structure comprises a first portion and a pair of second portions, the first portion is isolated from the plurality of through vias, and the pair of second portions are electrically connected to the plurality of through vias.

5. The semiconductor device as claimed in claim 4, wherein the second die and the third die are electrically connected to each other through the first portion.

6. The semiconductor device as claimed in claim 1, wherein the plurality of second connectors comprises a plurality of signal terminals electrically connected to the first die through the plurality of first connectors.

7. The semiconductor device as claimed in claim 1, wherein the substrate comprises:
a core layer;
a first redistribution structure, located on a first surface of the core layer; and
a second redistribution structure, located on a second surface opposite to the first surface of the core layer,
wherein the first die is surrounded by the first redistribution structure.

8. The semiconductor device as claimed in claim 1, wherein the first die is provided under and connects to the second die and the third die.

9. A semiconductor device, comprising:
a substrate;
a first die, embedded in the substrate;
a plurality of first connectors, located between and electrically connected to the first die and the substrate;
a second die, located on a first surface of the substrate;
a third die, located on the first surface of the substrate;
an encapsulant, encapsulating the second die and the third die; and
a plurality of second connectors, located on a second surface opposite to the first surface of the substrate,
wherein a first signal routing between the second die and the plurality of second connectors is provided through one of the plurality of first connectors and the first die, and
a second signal routing between the third die and the plurality of second connectors is provided through another one of the plurality of first connectors and the first die.

10. The semiconductor device as claimed in claim 9, wherein the first die comprises a base portion, a power portion and a pair of signal portions, the pair of signal portions are penetrated through the base portion, and the power portion is floated in the base portion.

11. The semiconductor device as claimed in claim 10, wherein the first signal routing and the second signal routing pass through the pair of signal portions.

12. The semiconductor device as claimed in claim 10, wherein each of the pair of signal portions comprises a first interconnect layer and a plurality of through vias, the power portion comprises a second interconnect layer, and the second interconnect layer is spaced from the plurality of through vias.

13. The semiconductor device as claimed in claim 9, wherein orthographic projections of the second die and the third die on the substrate covers the first die.

14. The semiconductor device as claimed in claim 13, wherein the first die is partially overlapped the second die in a vertical direction and the first die is partially overlapped the third die in the vertical direction.

15. The semiconductor device as claimed in claim 9, wherein the first die is inserted between a plurality of conductive features of the substrate.

16. A manufacturing method of a semiconductor device, comprising:
providing a first die;
embedding and electrically connected the first die in a substrate by a plurality of first connectors;
bonding a second die to a first surface of the substrate;
bonding a third die to the first surface of the substrate;
encapsulating the second die and the third die by an encapsulant; and
forming a plurality of second connectors located on a second surface opposite to the first surface of the substrate,
wherein a first signal routing between the second die and the plurality of second connectors and a second signal routing between the third die and the plurality of second connectors are configured by the first die respectively.

17. The manufacturing method of a semiconductor device as claimed in claim 16, further comprising: forming an interconnect structure on a base material layer and a plurality of through vias in the base material layer to form the first die.

18. The manufacturing method of a semiconductor device as claimed in claim 16, wherein portions of the substrate are formed by a plurality of redistribution processes.

19. The manufacturing method of a semiconductor device as claimed in claim 18, wherein a plurality of conductive features formed by the plurality of redistribution processes is configured to surround the first die.

20. The manufacturing method of a semiconductor device as claimed in claim 16, wherein the first die is a passive device.
